(19) United States
(12) Patent Application Publication
(10) Pub. No.: US 2023/0121979 A1
(43) Pub. Date: Apr. 20, 2023

(54) PHOTOVOLTAIC DEVICE AND METHOD FOR MANUFACTURING THE SAME

(71) Applicant: Meyer Burger (Germany) GmbH, Hohenstein-Ernstthal (DE)

(72) Inventor: Damien LACHENAL, Cortaillod (CH)

(21) Appl. No.: 17/914,649

(22) PCT Filed: Mar. 11, 2021
(86) PCT No.: PCT/EP2021/056160

§ 371 Date: Sep. 26, 2022

(30) Foreign Application Priority Data
Mar. 27, 2020 (EP) 20166232.7

(51) Int. Cl. H01L 31/05; H01L 31/077; H01L 31/18; H01L 31/20; H01L 23/544

(52) U.S. Cl. CPC H01L 31/0516; H01L 23/544; H01L 31/077; H01L 31/202; H01L 31/1804

(57) ABSTRACT

Disclosed is interdigitated back contact (IBC) photovoltaic devices and modules that are based on a silicon structured device which includes: a silicon-based substrate, an intrinsic amorphous silicon layer a-Si:H(i) situated on substrate a first patterned silicon layer, and a second patterned nano-crystalline silicon layer on the first patterned silicon layer. The second patterned layer is of the same type of doping than the first patterned silicon layer The first patterned layer and the second patterned layer form photovoltaic structures, of which at least one constitutes a fiducial mark having, in a predetermined wavelength range, a different optical reflectivity, than the reflectivity of the intrinsic amorphous silicon (a-Si:H(i)) layer portions interstices between the photovoltaic structures. Also disclosed are a photovoltaic device, photovoltaic modules and a method of fabrication of the photovoltaic device.

### TECHNICAL FIELD

The present invention relates to the field of photovoltaic devices. More particularly, it relates to a photovoltaic device with back-contacts being of the interdigitated back contact (IBC) type in which the collecting material is patterned. The invention relates particularly to devices comprising a tunnel junction on the back of the device. The invention also relates to a method for producing such photovoltaic devices.

A particular advantageous application of the present invention is for the production of highly efficient photovoltaic cells intended for generating electrical energy, but the invention also applies, more generally, to any similar device in which an incoming radiation is converted into an electrical signal, such as photodetectors and ionizing radiation detectors.

### BACKGROUND OF THE INVENTION

Interdigitated back-contact silicon heterojunction solar cells (IBC-SHJ), while being highly efficient, present difficulties due to their highly complex processing. Indeed, the realization of IBC-SHJ devices requires patterning the rear a-Si:H layers and TCO/metal stacks into interdigitated combs, with a very high accuracy. Most of the techniques known from the state-of-the-art rely on the use of complex and costly processes. Examples are described in for example the following papers:
Efficient interdigitated back-contacted silicon heterojunction solar cells, N.Mingirulli et al, Phys.status solidi-Rapid Res.Lett., vol.5, nr.4, pp.159-161, April 2011;
The role of back contact patterning on stability and performance of Si IBC heterojunction solar cells, U.K.DAS et al., Proceedings of the 40the IEEE Photovoltaic Specialist Conference, 2014, vol.1;

One of the outstanding difficulties of the known processes to make IBC solar cells such as tunnel junction IBC photovoltaic devices, especially in high volume production machines, is related to the use of commonly known standard alignment techniques to align deposition masks and a wafer during the PECVD step. Known alignment techniques in the field of interdigitated back-contact silicon heterojunction solar cells rely solely on the need of an absolute mask-to-wafer positioning. Such alignment techniques require a very high accuracy, i.e. better than 5 µm, leading to a severe limitation of the mask alignment automation, especially under vacuum environment. Current alignment techniques impose slow processes to be highly accurate and need expensive and optical alignment tools, limiting severely the production throughput. The required high accuracy of better than 5 µm when positioning several masks for different process steps is also a source of loss of production yield.

As an example of such a limitation in existing processes, the following publication describes a double amorphous microcrystalline structure for locally deposited structures: Andrea Tomasi et al. “ Simple processing of back-contacted silicon hetero-juntion solar cells using selective area crystalline growth,”, Nature Energy, vol.2, nr.5, 24 Apr. 2017, XP055726601. This publication describes the natural growth characteristic when growing a micro-, nano- or protocrystalline layer on top of an amorphous layer. Such a layer has a mixed phase with at the most an amorphous nucleation region which serves only as a start of the nucleation process. Such a growth of a nano- micro- or protocrystalline layer cannot be controlled directly and the contrast between the structured (masked) silicon contacts and non-structured silicon contacts that would be needed to guarantee a reliable alignment of the next conductive electrodes, made of a patterned transparent conductive oxide and screen-printed silver fingers, is not sufficient. Therefore, in the publication of Tomasi et al., the alignment of the mask when placed onto the wafer has to be absolute, i.e. using the wafer edges for example, thus limiting the production throughput and yield. In others words, without the definitive control of the thickness of the first doped amorphous layer below the first doped nano-crystalline layer it will be difficult, if not impossible, to guarantee a sufficient contrast between structured and non-structured silicon contact areas, which requires an indirect alignment of the conductive contact structures to the silicon contact structures i.e. with the help of the alignment to the wafer edges.

Another IBC solar cell is described in: D.Lachenal et al. “Optimization of tunnel-junction IBC solar cells based on a series resistance model”, Solar Energy Materials and Solar Cells, vol.200, 9 Jul. 2019, XP085797565. The description in the document of Lancheal et al. stays quiet about how to realize a reliable, repeatable and automated alignment steps. Developments have shown that with the deposition of a nanocrystalline layer alone, the detection of such structures, necessary for the alignment of the conductive contact structures, is not at all reliable and would not be possible to be used to realize IBC cells at an industrial level.

### SUMMARY OF THE INVENTION

The present invention proposes to improve commonly known standard alignment techniques to align deposition masks and a wafer during the PECVD step of the fabrication of photovaltaic cells. Therefor, the invention provides fiducial marks that avoid current alignment techniques which rely solely on the need of an absolute mask-to-wafer positioning. The invention as described herein is about how to provide novel and improved fiducial marks that enable the visibility of the fiducial, in reflection and/or in transmission, in the PECVD step for later processing even if the fiducial mark is made of the same material as the base substrate and at the same time very thin.

In a first aspect the invention relates to a silicon structured device, that is used as an intermediate product to make interdigitated back contact (IBC) photovoltaic devices and modules. The silicon structured device comprises:
a silicon-based substrate being of p-type or n-type doping and having a first face defining a horizontal X-Y plane and a vertical direction Z orthogonal to said horizontal X-Y plane;
an intrinsic amorphous silicon layer a-Si:H(i) situated on said first face;
a first patterned silicon layer, situated on said intrinsic amorphous silicon layer a-Si:H(i) layer, comprising a first array of distinct and separated amorphous layer islands so that between the amorphous layer islands non-coated, intrinsic amorphous silicon (a-Si:H(i)) layer portions are provided that define an array of interstices, said first patterned silicon layer having the same doping as the doping of the silicon-based substrate.

A second patterned nano-crystalline silicon layer is in contact with said first patterned silicon layer, comprising a second array of second layer portions, each of said second layer portions being in contact with one of said first layer portions and forming an array of silicon structures.

A second array of second layer portions is of the same type of doping than said first patterned silicon layer.

At least one of the silicon structures constitutes a fiducial mark having, in a predetermined wavelength range, a different optical reflectivity R1, defined to the side away from said substrate, than the reflectivity R0 of said intrinsic amorphous silicon (a-Si:H(i)) layer portions, said fiducial mark may have also a different optical transmittivity T1 than the transmittivity T0 of said intrinsic amorphous silicon (a-Si:H(i)) layer portions, said optical transmissivity (T1).

The advantage of the use of a silicon structured device of the invention, in the fabrication of photovoltaic devices and modules according to the invention, is that only the dedicated additional deposition of a pure amorphous silicon layer of a certain and dedicated thickness between the intrinsic layer and the doped nano-crystalline layer guarantees a sufficient optical contrast to enable a reliable detection of the localized silicon structures. This solves a long-standing fabrication problem. In prior art photovoltaic device that rely on the deposition of a nano-crystalline layer alone, the optial detection of the structures, necessary for the alignment of the conductive contact structures, would be very difficult to achieve and would not be possible to be used in an industrial fabrication process. Indeed, the growth of a nano- micro- or protocrystalline layer cannot be controlled directly and the contrast between the structured (masked) silicon contacts and non-structured silicon contacts is totally insufficient and cannot be used in a production environment.

In an embodiment the absolute value of (R1-R0)/R0 is between 0.001 and 0.5, preferably between 0.005 and 0.1, more preferable between 0.09 and 0.2 for at least one wavelength, R0 and R1 being defined for wavelengths between 300 nm and 1000 nm.

In an embodiment the silicon structured device comprises at least two fiducials.

In an embodiment at least one of said fiducials has a different shape and/or or different dimension, in at least one cross section plane (XY, YZ, XZ), than the shape and/or the dimension of the silicon structures that provide, in the photovoltaic device of the invention electric charge collecting structures.

In an embodiment the silicon structured device comprises at least 2 fiducial marks having a different shaped cross section in at least one plane parallel to said horizontal X-Y plane.

The invention is also achieved by a photovoltaic device comprising the silicon structured device. The photovoltaic device comprises an additional silicon layer that is arranged on said second patterned nano-crystalline silicon layer, and that covers said silicon structures and said interstices. The additional silicon layer has a doping of the other type than the first patterned silicon layer and defines mesas on the silicon structures. The mesa on said at least one fiducial has a reflectivity R3 than the reflectivity of said interstices R2 so that and wherein said at least one fiducials are optically detectable by optical means through said additional silicon layer.

In an embodiment of the photovoltaic device, a transparent and conductive second layer is present on said additional silicon layer, covering said mesas and said third layer interstices, so that the at least one coated fiducial has a reflectivity R5 different than the reflectivity R4 of its surroundings and so that said at least one coated fiducial is optically detectable by optical means through said additional silicon layer and said second full area layer.

The invention is also achieved by a photovoltaic module comprising at least one photovoltaic device as described. The photovoltaic module comprises electrical conducting elements, preferably electrical conducting layers or wires.

The invention is also achieved by a method for manufacturing of a silicon structured device as described, comprising the steps (a-c) of:
a. providing a silicon-based substrate having an n-type or a p-type doping and comprising an intrinsic amorphous a-Si:H(i) layer situated on a first face of said silicon-based substrate;
b. realizing, on predetermined areas of said intrinsic layer, a first deposition of an n-type or p-type amorphous silicon layer, so as to create a patterned amorphous silicon layer comprising a plurality of distinct and separated amorphous layer islands separated by interstices ;
c. realizing on each of said amorphous layer islands a second deposition of a nano-crystalline layer having the same doping type as said amorphous layer, so as to create on top of each of said amorphous layer islands, nanocrystalline layer portions, to form an array of photovoltaic structures, while choosing the thickness (t) of said first amorphous layer portions so that at least one fiducial is formed that has a different optical reflectivity (R1), defined to the side away from said substrate, than the reflectivity (R0) of the said intrinsic amorphous silicon (a-Si:H(i)) layer portions.

The invention is also achieved by a method to realize a photovoltaic device. In an embodiment of the method to realize a photovoltaic device, after step c, a step d is performed consisting in depositing, on top of the silicon structures said intrinsic amorphous silicon (a-Si:H(i)) layer portions, a full area semiconductor layer, having a doping type different than the doping type of said second nano-crystalline layer so that said at least one fiducial may be detected by optical means through said full area semiconductor layer. After having executed step a photovoltaic device is formed that allows to separate the electric charges generated by the absorbed photons.

In an embodiment, after said step d, a step e is realized consisting in depositing a second layer on top of said semiconductor layer and so that said at least one fiducial may be detected by optical means through said full area semiconductor layer and second full area layer.

In an embodiment the thickness t2 of said second layer is chosen so that, by constructive interference, reflected light off said at least one fiducial is transmitted through said second layer, in at least one wavelength range defined in the UV, visible or infrared optical spectrum.

In an embodiment the realization of said at least one fiducial is made by using a mask comprising at least one conical shape aperture, said conical shape being defined in at least one plane orthogonal to said horizontal X-Y plane and so that at least one fiducial has a greater height (h) than said electric charge collection structures.

In an embodiment the deposition of said amorphous layer islands and the deposition of the nanocrystalline layer islands are made through the same mechanical mask.

The invention is also achieved by a use of a silicon structured device, as described, to realize a photovoltaic device.

The invention is also achieved by the use of at least one photovoltaic device, as described, to realize a photovoltaic module.

### BRIEF DESCRIPTION OF THE DRAWINGS

The present invention will now be described in reference to the enclosed drawings where:

FIG. 1 is a schematic cross-section view of a portion of a silicon structured device of the invention comprising fiducials each made of a portion of a-Si:H(n) layer and a portion of a nc-si:H(n) layer. The figure also illustrates an array of silicon structures that are the base of electric charge collecting structures of the photovoltaic devices and modules according to the invention;

FIG. 2 is a schematic cross-section view of a fabrication step of a portion of a photovoltaic device, illustrating a mechanical shadow mask for realizing an optical detectable fiducial realized by the superposition, through the mask, of a portion of a a-Si:H(n) layer and a portion of a nc-si:H(n) layer;

FIG. 3 is a schematic cross-section view of an embodiment of a fabrication step of a portion of a photovoltaic device, illustrating a mechanical shadow mask for realizing an optical detectable fiducial realized by the superposition, through the mask, of a portion of a a-Si:H(n) layer and a portion of a nc-si:H(n) layer, the mask layer comprising two conical shaped apertures;

FIG. 4 is a top view of a portion of a photovoltaic device of the invention comprising two fiducials each made of a portion of a-Si:H(n) layer and a portion of a nc-si:H(n) layer. The figure also illustrates an array of electric charge collecting structures;

FIG. 5 is a top view of a portion of a photovoltaic device comprising two fiducials and an array of charge collecting structures that are covered entirely by a first , preferably full, area layer that has an opposite doping than the doping of the substrate of the photovoltaic device;

FIG. 6 illustrates a top view of a portion of a photovoltaic device comprising a second area layer, possibly a full area layer, made of for example ZnO:Al, covering entirely the first full area layer of FIG. 5. FIG. 6 illustrates that the fiducial marks of the invention are optically detectable through said second full area layer, and are used to patterned a conductive and transparent layer as illustrated in the FIG. 8;

FIG. 7 illustrates a cross section view of the photovoltaic device of FIG. 5, demonstrating the difference in reflectivities of the fiducials and its interstices. FIG. 7 illustrates the state of realization of a photovoltaic device before deposition of an area conductive and transparent layer, that may be a full area layer. The alignment fiducials in FIG. 5 are used to realize a patterned conductive and transparent layer as illustrated in the next FIG. 8;

FIG. 8 illustrates a typical realization of a back-contact of the device of the invention, prior the final metallization step. FIG. 8 shows a conductive and transparent layer after the patterning step of a full area conductive and transparent layer by using the alignment fiducials of the invention;

FIG. 9 illustrates another realization of a back-contact of the device of the invention;

FIG. 10 illustrates reflectivities and transparencies from and through fiducials of the invention that are coated with a layer having a doping opposite of the doping of the fiducials;

FIG. 11 illustrates reflectivities and transparencies from and through fiducials of the invention that are coated with a transparent and conductive layer;

FIG. 12 illustrates the difference in reflectivity of a photovoltaic device on top of a fiducial mark of the invention, comprising an amorphous a-Si:H(n) layer and of the area beside that fiducial that has no a-Si:H(n) layer. The reflectivity curves of FIG. 10 demonstrate the benefit of using a layer of a-Si:H(n) in the fiducial of the invention, to enhance the contrast in the case of a typical visible spectrum;

FIG. 13 illustrates the transmission difference between fiducials that comprise an amorphous a-Si:H(n) layer and a fiducial that does not comprise an amorphous a-Si:H(n) layer.

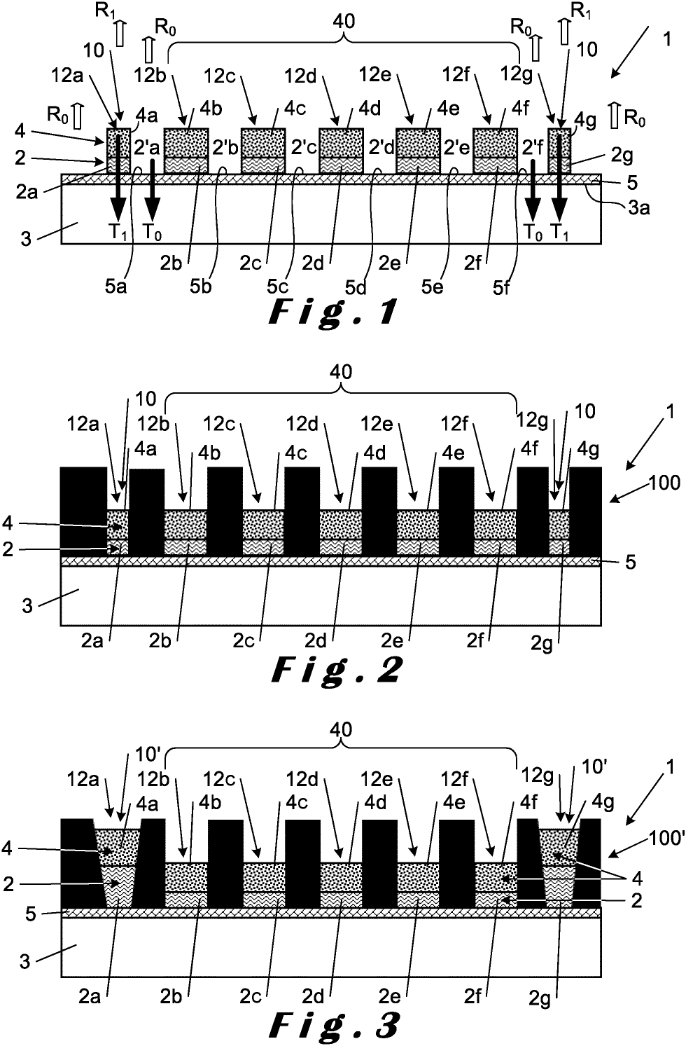

### DETAILED DESCRIPTION

The present invention will be described with respect to particular embodiments and with reference to certain drawings, but the invention is not limited thereto. The drawings described are only schematic and are non-limiting. In the drawings, the size of some of the elements may be exaggerated and not drawn on scale for illustrative purposes. The dimensions and the relative dimensions do not correspond to actual reductions to the practice of the invention.

It is to be noticed that the term “comprising” in the description and the claims should not be interpreted as being restricted to the means listed thereafter, i.e. it does not exclude other elements.

Reference throughout the specification to “an embodiment” means that a feature, structure or characteristic described in relation with the embodiment is included in at least one embodiment of the invention. Thus, appearances of the wording “in an embodiment” or, “in a variant”, in various places throughout the description are not necessarily all referring to the same embodiment, but several. Furthermore, the features, structures or characteristics may be combined in any suitable manner, as would be apparent to a skilled person from this disclosure, in one or more embodiments. Similarly, various features of the invention are sometimes grouped together in a single embodiment, figure or description, for the purpose of making the disclosure easier to read and improving the understanding of one or more of the various inventive aspects. Furthermore, while some embodiments described hereafter include some, but not other features included in other embodiments, combinations of features if different embodiments are meant to be within the scope of the invention, and from different embodiments. For example, any of the claimed embodiments can be used in any combination. It is also understood that the invention may be practiced without some of the numerous specific details set forth. In other instances, not all structures are shown in detail in order not to obscure an understanding of the description and/or the figures.

A horizontal plane herein is defined as a X-Y plane parallel to a face of the substrate 3. The wording “horizontal cross section means a cross section in a X-Y plane. The wording “vertical means” here perpendicular to the substrate and defines a Z-axis. A vertical cross section is a cross section in a X-Z or Y-Z plane that comprises the vertical axis Z. A radial direction means a direction defined in a horizontal cross section. A lateral direction is defined in an X and/or Y direction in a horizontal plane. A width is defined as a width of a structure across a virtual line in a horizontal plane., said width is also defined as a diameter. Thicknesses are defined herein as thicknesses in the vertical Z- direction.

The term “fiducial” herein means an alignment mark, also defined as a fiducial mark 10, 10′.

The term “full area layer” used herein is defined as a layer deposited on a whole surface, for example of a whole substrate 3.

The term “silicon structured device” and “silicon structures” mean herein a device that comprises silicon structures on its surface, to be used for the manufacturing of photovoltaic devices. Used alone they are not used as a device to convert light into electrical charges but as an intermediate product.

The invention provides an IBC solar cell, such as a tunnel-junction IBC photovoltaic devices that can be produced with a low-cost process especially in high volume production machines. The method and devices of the invention improves current alignment techniques which rely solely on the need of an absolute mask-to-wafer positioning. Such alignment techniques require a very high accuracy, i.e. better than 5 µm, leading to a severe limitation of the mask alignment automation. Furthermore, the mask alignment better than 5 µm in a high throughput PECVD machine (>6000 wafers per hour) remains a complex problem considering the global environment. Especially, the deposition temperature (150° C.-250° C.) leads to material dilatations (mask, wafer holder) and the vacuum environment prevents the use of low-cost alignment technics such as standard cameras. These constraints impose slow processes and require expensive optical alignment tools, limiting severely the production throughput. The required high accuracy of better than 5 µm is also a source of loss of production yield. It is therefore needed to find an alternative solution allowing the alignment preferably at room temperature, in a standard atmosphere (i.e. not under vacuum) and at a high speed to decrease the global manufacturing cost of such a solar cells.

The invention as described herein is about how to make or better deposit fiducials 10 to enable visibility of the fiducial in the PECVD step for later processing even if the fiducial mark 10 is made of the same material as the base substrate and at the same time very thin.

The proposed solution solves the problem of expensive mask and wafer automation by postponing the alignment procedure between the silicon N and P junctions and the final metallization step in the following way.

Instead of an accurate mask to wafer positioning better than 5 µm using a standard wafer edge alignment method at the PECVD step, the solution relaxes the alignment constraint to a range of 300 µm - 500 µm by the use of fiducial openings integrated into the required mask. By doing so, the mask positioning is relaxed and can be done in a passive way without camera, decreasing considerably the automation cost. Next, the metallization step, which needs to be aligned with the previous deposited silicon N & P junctions is done with standard screen-printing machines. These machines, mostly equipped with cameras working in the visible wavelength range, easily align within an accuracy of 5 µm and at high throughput as soon as they are capable to recognize, at least, a pair of fiducials, or a fiducial having a specific shape on the wafer. The novelty and inventive aspect resides in the fact that the fiducial material composition is done during the PECVD step, so that for example a screen printer machine is able to recognize the fiducial(s) 10 and enable to align the metallization screen on previously deposited N and P silicon junctions.

An efficient tunnel junction, in a back contacted solar cell application, is made typically of an N-type doped nano-crystalline silicon layers deposited through a mask, and a -P-type doped nano-crystalline silicon layer that forms at the same time the tunnel junction itself (N polarity) and the emitter layer (P polarity). For efficient production the second, p-type doped layer, is deposited without a mask and hence covering both, the localized and structured n-type layer, as well as the interstices between these structures. Both, p- and n-type layers, embed a high fraction of silicon crystals at the nano-meter scale, within a thickness layer of 30-80 nm. These N and P layers are optically very close to the optical index (n, k) of the also crystalline silicon bulk wafer 3. The addition of an intrinsic, amorphous silicon layer a-Si:H(i) 5 ,typically used as an effective passivation layer in heterojunction based solar cells is not sufficient to guarantee an effective optical separation of the mostly nano-crystalline structures from the crystalline substrate due to its thickness of typically less than 10 nm. It is therefore impossible, if done in that way, to detect any optical difference between the pattern of the P and N polarities with the common screen printer cameras, as both layers are made of the same crystalline silicon composition. The invention consists in solving this technical problem by providing a new type of fiducial marks 10.

The novelty and inventive step, proposed in this invention, has been to develop a material composition of the fiducials, so that their optical indices are significantly different compared to the bulk silicon wafer - coated with an intrinsic a-Si:H(i) amorphous silicon layer - without degrading the electrical performance of the tunnel junction itself. By implementing the solution of the invention, a solar cell efficiency can reach its best performance and can be aligned with standard screen printer machines at room temperature and at atmospheric pressure, enabling the manufacturing of such IBC solar cells at low cost.

Practically, by depositing an n-doped amorphous silicon layer 2 prior to the n-doped nano-crystalline layer through the mask, alignment marks are provided that become visible to printer cameras that mostly work in the visible wavelength range. The use of such an amorphous layer 2 enhances the contrast between the silicon wafer 3 and the fiducials 10 as their optical properties n(λ), k(λ) differ. Physically, the optical index of the localized fiducials of the invention are made of a stack of layers that are successively nano-crystalline(p), nano-crystalline(n), amorphous-silicon(n), amorphous-silicon(i), substrate 3, while the surrounding area of the fiducials is made of nano-crystalline(p)/amorphous silicon(i)/substrate 3 material. The change in reflectivity of the fiducials 10 is also achieved by adjusting the thickness of the structured amorphous silicon layer 2.

The n-doped amorphous silicon layer 2 being thin (5-15 nm range), the electrical transport through this layer is not degraded and the electrical performance of the tunnel junction is maintained. The novelty and inventive step of the solution of the invention resides in the fact that reflectivity of the deposited silicon layer is modified locally through the shadow mask compared to the silicon bulk wafer without increasing the electrical resistance of the tunnel junction.

More precisely the invention proposes a silicon structured device 1, being an intermediate product to realize interdigitated back contact (IBC) devices. The silicon structured device 1 comprises:
a silicon-based substrate 3 being of p-type or n-type doping and having a first face 3a defining a horizontal X-Y plane and a vertical direction Z orthogonal to said horizontal X-Y plane;
an intrinsic a-Si:H(i) amorphous silicon layer 5 situated on said first face 3a;
a first patterned silicon layer 2, situated on said intrinsic a-Si:H(i) amorphous silicon layer 5, comprising a first array of distinct and separated amorphous layer islands 2a-2g. These amorphous layer islands 2a-2g are separated by an array 2′ of interstices 2a′ -2g′. In these interstices, which are apertures of the first patterned silicon layer 2, intrinsic amorphous silicon (i.e. a-Si:H(i)) layer portions 5a-5f, defined also as interstitial portions 5a-5f, are present, which are the portions of the amorphous silicon layer 5 on which there are no amorphous layer portions. Said first patterned silicon layer 2 has the same doping as the doping of the silicon-based substrate 3,
a second patterned nano-crystalline silicon layer 4 in contact with said first patterned silicon layer 2, comprising a second array of second layer portions 4a-4g, each of said second layer portions 4a-4g being in contact with one of said first layer portions 2a-2g and forming an array 40 of silicon structures 12a-12g, as illustrated in FIG. 1. Most 12b-12f of the silicon structures are the basis for charge collecting structures of the photovoltaic device and modules of the invention and the remaining structures 12a, 12g are alignment marks or are charge collecting structures that are used as alignment marks. There is at least one silicon structure 12a that is used as an alignment mark or is an alignment mark. As explained further the structures used as alignment mark may be different in shape, composition or have a different coating than the silicon structures that are a base for said charge collecting structures 12b-12f. As explained further, alignment marks may have the shape of dots or may present a form that allows to defined directions in the X-Y plane such as an L-shaped form or other.
It is understood that the second layer portions 4a-4g -might not have the same lateral dimensions as the lateral dimensions of said amorphous layer islands 2a-2g.

Said second array of second layer portions 4a-4g is of the same type of doping than said first patterned silicon layer 2. In embodiments the level of doping of second layer portions 4a-4g may be different than the level of doping of said first patterned silicon layer 2.

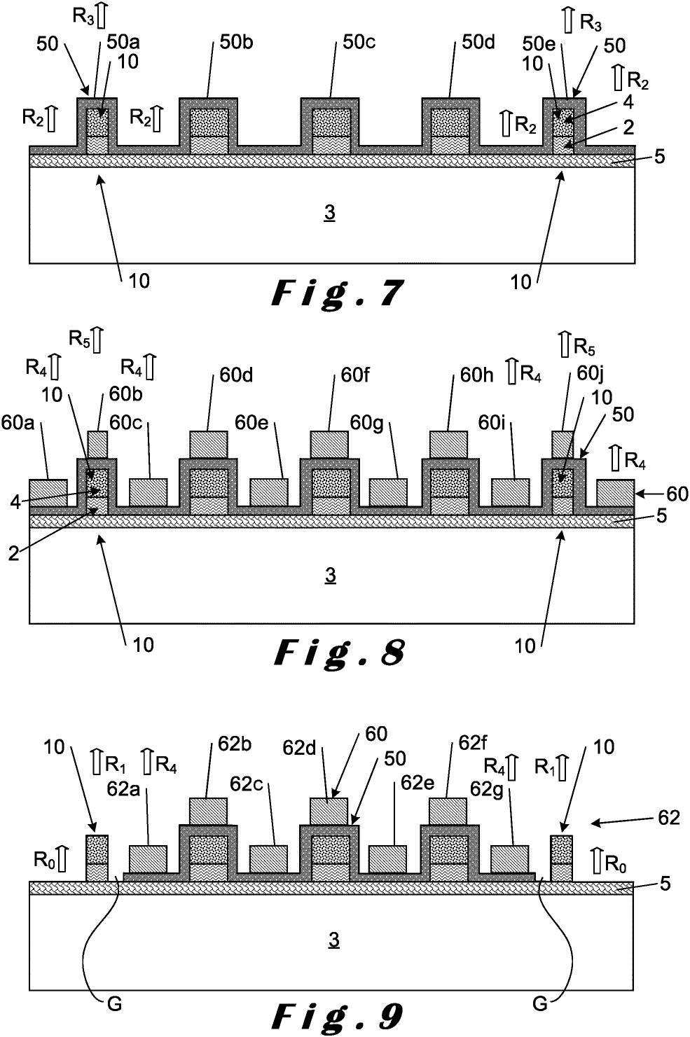

At least one of said silicon structures 12a, 12g constitutes a fiducial mark 10 having an optical reflectivity R1, defined to the side away from said substrate 3, that is different than the reflectivity R0 of said intrinsic amorphous silicon (i.e. a-Si:H(i)) layer portions 5a-5f as illustrated by the respective symbols RO and R1 in FIG. 1 and in an embodiment illustrated in FIG. 9, at least in a certain wavelength rage.

In an embodiment, the optical reflectivity R1 of the fiducial marks 10 may be greater or smaller than the reflectivity R0 of the interstitial portions 5a-5f of the intrinsic amorphous layer 5.

In embodiments the absolute value of (R1-R0)/R0 may be between 0.001 and 0.5, preferably between 0.005 and 0.1, more preferable between 0.09 and 0.2, the reflectivities R0 and R1 being defined for a wavelength range between 300 nm and 1000 nm. In practice, a difference of some % between the values of R1 and R0 is sufficient to provide optical detection of the presence of the fiducial marks 10, 10′ in the device 1 of the invention Without the composition of an amorphous layer portion 2a, 2g and a nano-crystalline layer portion 4a, 4g, as illustrated in FIG. 1 the silicon structures 12a, 12g, that constitute fiducial marks 10, the alignment with other parts would not be possible. Such other part may be:
electrical contact structures
masking structures/layers to protect deposited layers from a partial back etch or to avoid local short circuits during further processing steps (i.e. interconnections by wires or ribbons).

Indeed, the index of refraction may be adapted so that the reflectivity of the fiducial marks 10 may be adapted to provide a great contrast with the surrounding intrinsic amorphous layer portions 5a-5f.

Typically, the first layer portions 2a-2g have a diameter of 500 µm to 1 mm and thickness between 5 nm to 30 nm. The thickness of the second layer portions 4a-4g is between 15 nm to 80 nm.

It is understood that the invention is not limited to the exemplary value ranges of R1 and R0 as explained above.

In the device of the invention all photo voltaic structures are electrically conductive. The fiducials marks 10 are electrically conductive because of the used process. In embodiments, an electrical isolation layer may be arranged between the intrinsic amorphous layer 5 and the fiducials 10, i.e. between the intrinsic amorphous layer 5 and the amorphous fiducial portions 2a, 2g.

In particular embodiments, in view of enhancing the optical contrast between the fiducials and their surrounding layers, such as the intrinsic amorphous layer portions 5a-5f, the fiducials may incorporate materials that are not present in the other photovoltaic structures 12b-12f. For example, ion implants may be realized in said fiducials 10 and not in the other photovoltaic structures12b-12f. Also, in variants, the crystal and/or structural matrix composition of the fiducials 10 may be different, at least partially, than the other photovoltaic structures 12b-12f.

In variants, not illustrated, an additional contrast layer may be deposited only at the site of the fiducials 10 and not on the other photovoltaic structures 12b-12f. In a variant said optical contrast layer may be realized by a laser treatment, at least partially inside the volume of the fiducials 10, or by treating its upper surface to the side away from said substrate 3. In a variant, for example, a thermal and/or or laser treatment may alter the surface roughness of the fiducials to create a different optical reflection property than the reflection properties of the other photovoltaic structures 12b.12f.

In an embodiment, the silicon structured device 1, and so also the photovoltaic device of the invention, comprises at least two and possibly different fiducials 10, 10′. For example, the silicon structured device 1 1 may comprise 3 fiducial marks arranged in the form of a triangle, or may comprise a great number of fiducial marks that may be arranged according to an array that present a form dependent of the layout of the charge collecting structures, for example a circular, a square or a rectangular layout form.

In an embodiment, at least one of said fiducials 10,10′ has a different shape and/or or different dimension, in at least one cross section plane (i.e. in a XY, YZ, XZ plane), than the shape and/or the dimension of said electric charge collecting structures 12b-12f.

In an embodiment the photovoltaic device 1, comprises at least 2 fiducials 10, 10′ having a different shaped cross section in at least one plane parallel to said horizontal X-Y plane.

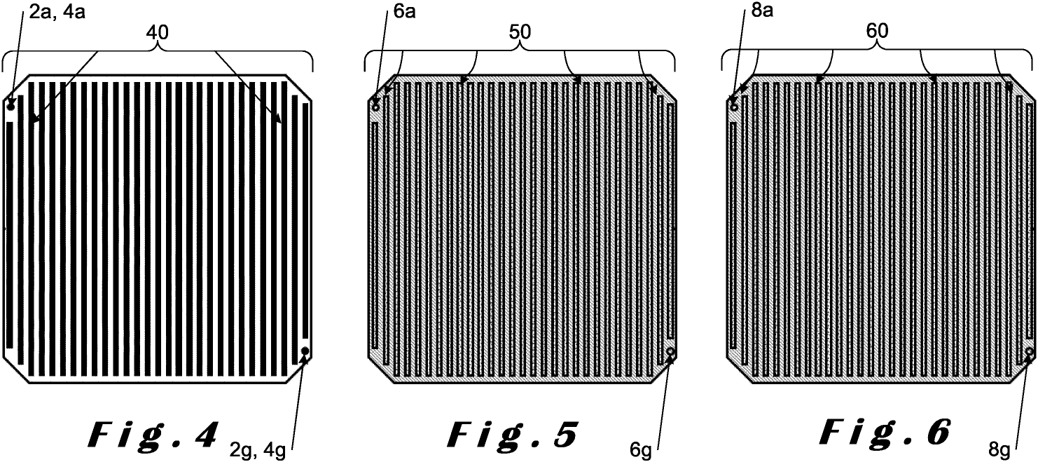

In an embodiment illustrated in FIG. 3: at least one fiducial 10, 10′ has a conical shape defined in at least one plane orthogonal to said horizontal X-Y plane.

In an embodiment at least one of said fiducials 10 is made of a plurality of dots forming a pattern.

The invention is also achieved by a photovoltaic device and photovoltaic modules that comprise the silicon structured device 1 of the invention.

In an embodiment, illustrated in FIG. 7, a third layer 50, which is preferably an at least partial transparent silicon layer 50, covers the silicon structured device 1, the structures 12a-12f and the interstitial portions 5a-5f of the intrinsic amorphous layer 5. This additional silicon layer 50 has a doping of the other type than the amorphous layer portion 2a, 2g and the nano-crystalline layer portion 4a, 4g. By depositing said at least partial transparent silicon layer 50, contacts of the opposite type to the contacts created by structures 12a-12f are created in the interstices 5a-5f and by that creating electrical charge separating contacts that are needed to realize a photovoltaic device. As illustrated in FIG. 7, said third layer 50 is a blanket layer and its deposition provides a plurality of third layer portions 50a-50e separated by third layer interstices. Said third layer portions 50a-50e have in practice the form of beams, defied also as fingers, arranged in an X-Y plane. The portion 50a, 50e of the third layer coating 50 that are on top of the fiducial mark structures 12a, 12g form coated fiducial marks 50a, 50g that has a reflectivity R3 different than the reflectivity R2 of said third layer interstices, as illustrated in FIG. 7. Because of the difference between the optical reflectivity R1 of the fiducial marks 10 and the reflectivity R0 of the interstitial portions 5a-5f of the intrinsic amorphous layer 5, as described above, the fiducial marks 10 are optically easily detectable by optical means through said additional silicon layer 50,

The fiducial mark can still be detected through a further layer, also defined as second layer 60, deposited on said third layer 50. Said further layer 60 is typically a transparent and conductive layer, such as a TCO layer, as described hereafter. Furthermore, there may be a difference in reflectivity R3 and R2 after the deposition of said additional silicon layer 50a-50e so that the fiducial mark can be even more easily detected through said conductive and transparent layer 60.

Typical preferred thicknesses of the different layers 2, 4, 5 ,50, 60 are:
the intrinsic amorphous silicon layer a-Si:H(i) layer 5: 2 nm to 10 nm, preferably 3 nm.
the first patterned silicon layer 2: 5 nm to 15 nm, preferably 11 nm.
second patterned nano-crystalline silicon layer 4: 15 nm to 50 nm, preferably 25 nm.
the third layer 50: 10 nm to 40 nm, preferably 20 nm.
the transparent and conductive second layer 60: 30 nm to 300 nm, preferably 50 nm.

In embodiments, the absolute value of (R3-R2)/R2 may be between 0.001 and 0.5, preferably between 0.005 and 0.1, more preferable between 0.09 and 0.2. In practice a difference of some % between the values of R3 and R2 allows to provide optical detection of the presence of the fiducial marks 10, 10′ in the device 1 of the invention. The invention is not limited to the exemplary value ranges of R3 and R2 as explained above.

In an embodiment the second additional layer 60, arranged on said additional silicon layer 50, is a transparent conductive layer, that may be a full area layer, made at least partially of for example ZnO:Al or ITO (Indium Tin oxide) FIG. 6 shows that the fiducials 10 of the invention are optically detectable through the second additional layer 60 and before its patterning, by using the fiducials in the way as described further in detail in the method section.

FIG. 8 shows a conductive and transparent layer after the patterning step of a full area conductive and transparent layer (FIG. 5) by using the alignment fiducials 10 of the invention. FIG. 8 illustrates typical realization of a back-contact of the device of the invention. As illustrated in FIG. 8 and FIG. 11 , a first portion 60b, 60d, 60f, 60h, 60j of the structures are configured to extract negative charges, and the other portion 60a,60c,60e,60g, 60i are configured to extract positive charges upon incidence of light from the side of the substrate 3.

It is evident for electrical reasons that the portions of layer 60 (FIG. 9) must not connect the charge collecting structures having opposite polarities.

The invention provides also a complete solar cell that comprises preferably a metallization layer deposited on the Transparent Conductive Oxide layer. This may be realized by for example screen printing silver.

Like the third layer 50, the second additional layer 60 form with said photovoltaic structures and the third layer 50 structures that may have the form of beams or mesas 60a-60j. The portion 60a, 60e of the third layer coating 50 that are on top of the second additional layer 60 forms at least one coated fiducial mark 60a, 60g that has a reflectivity R5 different than the reflectivity R4 of its surrounding areas, as illustrated in FIG. 8. Because of the difference between the optical reflectivity R3 of the coated fiducial marks 10 and the reflectivity R2 of the interstitial portions of the third layer 50, as described above, the fiducial marks 10 are still optically detectable by optical means through said second additional layer 60.

In embodiments the absolute value of (R5-R4)/R4 may be between 0.001 and 0.5, preferably between 0.005 and 0.1, more preferable between 0.09 and 0.2. In practice a difference of some % between the values of R5 and R4 allows to provide optical detection of the presence of the fiducial marks 10, 10′ in the device 1 of the invention. The invention is not limited to the exemplary value ranges of R5 and R4 as explained above.

In embodiments at least two of the reflectivity values R1, R3, R5 may be identical. In other embodiments at least two of the interstice reflectivity values R0, R2, R4 may be identical.

FIGS. 4-6 show a top view on a horizontal cross section of a full wafer comprising:
in FIG. 4: the first patterned silicon layer 2 on which said second patterned nanocrystalline silicon layer 4 is deposited;
in FIG. 5 said third, semiconductor, layer 5 on top of the whole area covered with said second patterned nano-crystalline silicon layer 4;
in FIG. 6 a transparent and conductive layer 60 on top of said third layer 50.

It may be seen from the FIGS. 5 and 6 that the fiducial marks 10 (i.e. said layers 4a and 4g on top of said layers 2a and 4g) are visible through the third layer 50 that is a full semiconductor layer, and also visible through said transparent and conductive layer 60 on top of said third layer 50.

In embodiments, the shape of the top of said fiducials 10 may be altered before depositing said third layer 50 and consequently said transparent and conductive layer 60.

In embodiments, illustrated in FIG. 9 at least one fiducial mark 10 of the invention may remain non coated with said third layer 50 and/or said transparent and conductive layer 60. In the variant of FIG. 9 the third coating layer 50 is not covering the fiducial marks and is not contact with two fiducial marks 10 and presents a gap G between the fiducial marks 10 and the third layer 50. The width of the gap G may be between 500 µm to 1 mm. This configuration can be useful in case that the third coating layer 50 or transparent conductive layer 60 is deposited using a specific bottom-top plasma deposition approach instead of a classical top-bottom plasma deposition approach. In this specific case, the solar cell is positioned down on an open tray facing a plasma deposition device and the wafer edges and the fiducials 10 are shaded by the tray during the plasma deposition.

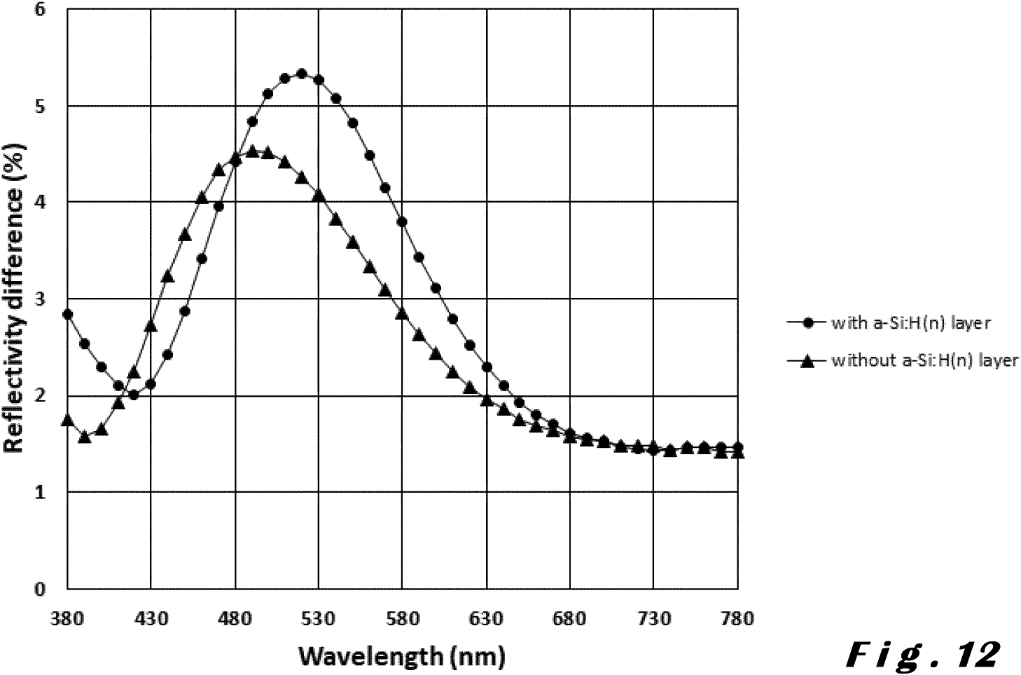

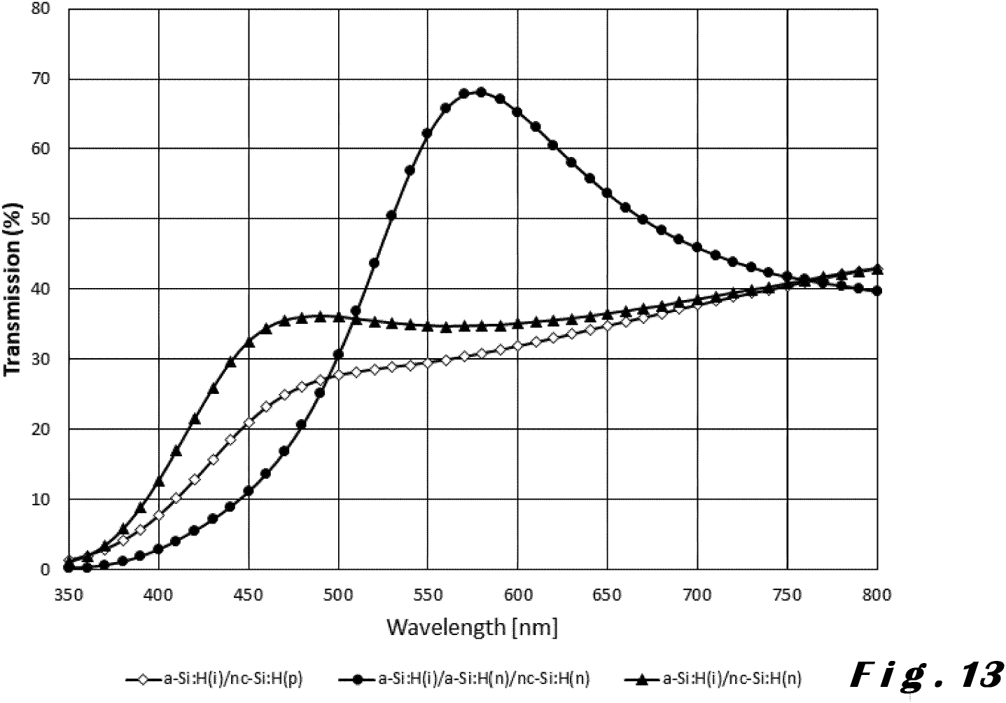

As illustrated in FIGS. 12 and 13 the optical transmission T1 of the fiducial marks 10 may be greater or smaller than the optical transmission T0 of the interstitial portions 5a-5f of the intrinsic amorphous layer 5.

In embodiments the absolute value of (T1-T0)/T0 may be between 0.001 and 0.5, preferably between 0.005 and 0.1, more preferable between 0.09 and 0.2, optical transmission T0 and T1 being defined for a wavelength range between 300 nm and 1000 nm. In practice, a difference of some % between the values of T1 and T0 is sufficient to provide optical detection of the presence of the fiducial marks 10, 10′ in the device 1 of the invention. The difference in optical transmission may be used in, for example, configurations wherein an infrared camera is used to detect the fiducials through a substrate that may be an at least partial optically transparent substrate. The invention is not limited to substrates made in Si.

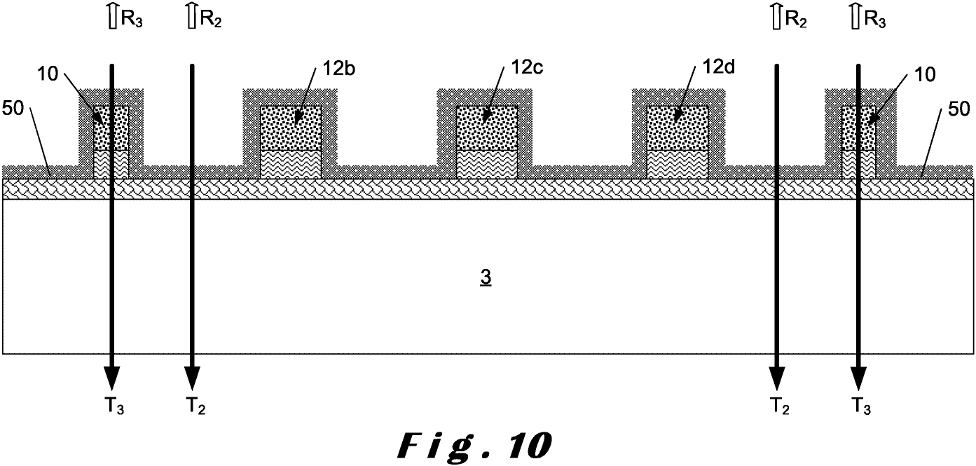

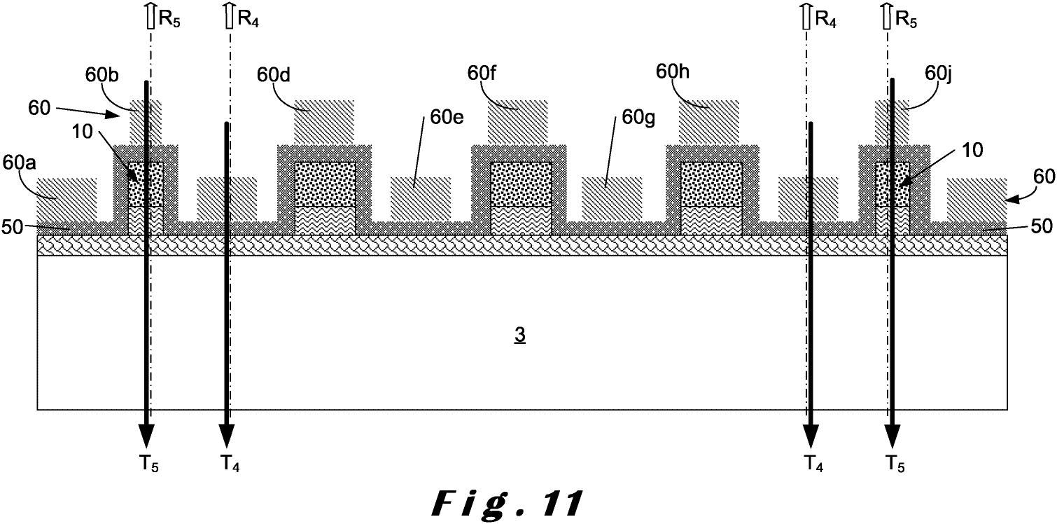

Similar to the transparency properties of the non -coated fiducials, coated fiducials may have also different transparencies relative to their interstices as illustrated in FIG. 10 and FIG. 11, i.e. T3 is different than T2 and T5 is different than T4.

The invention is also achieved by a photovoltaic cell comprising silicon structures as described above and that are used to provide fiducials during the fabrication of the photovoltaic cell.

The invention relates also to photovoltaic modules that are made of at least one photovoltaic cells of the invention. A photovoltaic module comprises at least one photovoltaic cell and other elements, such as for example a housing, and/or a protection layer and/or other photovoltaic cells.

The invention is also achieved by a method for manufacturing of a silicon structured device 1, to be used as an element in the fabrication of the photovoltaic devices and modules of the invention. The method comprises the steps a-c of:
a. providing a silicon-based substrate 3 having an n-type or a p-type doping and comprising an intrinsic amorphous a-Si:H(i) layer 5 situated on a first face 3a of said silicon-based substrate 3;
b. realizing, on said intrinsic layer 5, a first deposition of an n-type or p-type amorphous silicon layer 2, so as to create a patterned amorphous silicon layer 2 comprising a plurality of distinct and separated amorphous layer islands 2a-2g through a mask separated by interstices 2a'-2'g;
c. realizing, preferably by using the same mask, on each of said amorphous layer islands 2a-2g a second deposition of a nanocrystalline layer 4 having the same doping type as said amorphous layer 2, so as to create on top of each of said amorphous layer islands 2a-2g, nano-crystalline layer portions 4a-4g, to form an array of silicon structures 12a-12f. The realization of said amorphous layer islands 2a-2g is made by choosing the thickness of said first amorphous layer portions 2a-2g so that at least one fiducial 10 is formed that has a different optical reflectivity R1, defined to the side away from said substrate 3, than the reflectivity R0 of the said interstices 2a′-2g′.

In an embodiment a further step d may comprise the following deposition: a semiconductor layer 50 having a doping type different than the doping type of said second nano-crystalline layer 4 is arranged on top of said silicon structures 12a-12f and said interstices 5a-5f, so that said at least one fiducial 10, 10′ may be detected by optical means through said semiconductor layer 50 that is preferably a full area layer 50. As soon as step d has been executed the device is then a photovoltaic device 1 that may convert light into separated electrical charges.

In an embodiment, after said step d of realizing a full semiconductor layer 50, a step e is realized consisting in depositing a second area layer 60 on top of said full first area layer 50 and so that said at least one fiducial 10, 10′ may be detected by optical means through said first full area layer 50 and said second full area layer 60. Said second area layer 60 may be a full area layer. Said full first area layer 50 has a preferred thickness in a range of 15 to 40 nm. In an advantageous embodiment said second area layer 60 is an at least transparent and conductive layer such as a ZnO:Al. or an ITO (Indium Tin oxide) layer.

In an embodiment, the thickness t2 of second full area layer 60 is chosen so that, by constructive interference, reflected light off said at least one fiducial 10,10′ is transmitted through said second full area layer 60 in at least one wavelength range defined in the UV, visible or infrared optical spectrum. Said full first area layer 60 has a preferred thickness in a range of 30-300 nm.

In an embodiment the optical properties of said at least one fiducial 10, 10′ is determined during the fabrication process with an optical instrument.

Such an optical instrument may comprise a camera with image processing capabilities, or an interferometer that may comprise a laser. A monochrome camera using LEDs having a wavelength of the emitted light of 635 nm may be used advantageously.

In an embodiment, illustrated in FIG. 3, the realization of said at least one fiducial 10, 10′ is made by using a mask 100′ comprising at least one conical shape aperture, said conical shape being defined in at least one plane orthogonal to said horizontal plane giving at least one fiducial 10, 10′ which has a greater height h, defined in said Z-direction, than said electric charge collection structures 12b-12f.

In order to provide a full photovoltaic device an additional step f is performed that consist in depositing a metallization layer on the ZnO layer. This may be made by for example screen printing silver.

In another aspect the invention relates to the use of the silicon structured device 1, as described herein, to realize photovoltaic devices such as solar cells.

In a further aspect the invention relates to the use of the silicon structured device 1 as described, or said photovoltaic device, to realize a photovoltaic module made out of at least one of the said photovoltaic devices.

It is generally understood that the process and device of the invention may be applied to photovoltaic cell that rely on non-silicon devices, e.g. devices based on other semiconductors such as Germanium (Ge) based photovoltaic cells.

### Experimental Results

FIG. 10 illustrates the difference in reflectivity of a photovoltaic device on top of a fiducial mark of the invention, comprising an amorphous a-Si:H(n) layer and of the area beside that fiducial that has no a-Si:H(n) layer. FIG. 10 shows a typical required contrast of a fiducial 10 of the invention to allow its optical detection. The reflectivity curves of FIG. 10 demonstrate the benefit of using a layer of a-Si:H(n) in the fiducials 10 of the invention for enhancing the contrast in the case of a typical visible spectrum.

FIG. 11 illustrates the transmission difference between fiducials 10 that comprise an amorphous a-Si:H(n) layer and a fiducial that does not comprise an amorphous a-Si:H(n) layer.

1. A silicon structured device, designed to be used in a fabrication process of an interdigitated back contact (IBC) photovoltaic device, comprising:
a silicon-based substrate being of p-type or n-type doping and having a first face defining a horizontal X-Y plane and a vertical direction Z orthogonal to said horizontal X-Y plane;
an intrinsic amorphous silicon layer a-Si:H(i) situated on said first face;
a first patterned silicon layer, situated on said intrinsic amorphous silicon layer a-Si:H(i) layer, comprising a first array of distinct and separated amorphous layer islands so that between the amorphous layer islands non-coated intrinsic amorphous silicon (a-Si:H(i)) layer portions are provided that define an array of interstices , said first patterned silicon layer having the same doping as the doping of the silicon-based substrate,
a second patterned nano-crystalline silicon layer in contact with said first patterned silicon layer, comprising a second array of second layer portions, each of said second layer portions being in contact with one of said first layer portions and forming an array of silicon structures,
wherein
said second array of second layer portions is of the same type of doping than said first patterned silicon layer,
and wherein at least one of said silicon structures constitutes a fiducial mark having, in a predetermined wavelength range, a different optical reflectivity, defined to the side away from said substrate, than the reflectivity of said intrinsic amorphous silicon (a-Si:H(i)) layer portions.

2. The silicon structured device according to claim 1, wherein the absolute value of (R1-R0)/R0 is between 0.001 and 0.5 for at least one wavelength, said optical reflectivities R0, R1 being defined for wavelengths between 300 nm and 1000 nm.

3. The silicon structured device according to claim 1, comprising at least two fiducials.

4. The silicon structured device according to claim 1, wherein at least one of said fiducials has a different shape and/or or different dimension, in at least one cross section plane, than the shape and/or the dimension of said silicon structures.

5. The silicon structured device according to claim 3, comprising at least 2 fiducial marks having a different shaped cross section in at least one plane parallel to said horizontal X-Y plane.

6. A photovoltaic device comprising a silicon structured device according to claim 1, wherein an additional silicon layer is present on said second patterned nano-crystalline silicon layer, said additional silicon layer forming mesas covering said silicon structures and said interstices , said additional silicon layer having a doping of the other type than said first patterned silicon layer, the mesa on said at least one fiducial having a different reflectivity R3 than the reflectivity R2 of said interstices so that said at least one fiducial is optically detectable by optical means through said additional silicon layer.

7. The photovoltaic device according to claim 6 wherein a transparent and conductive second layer is present on said additional silicon layer, second layer covering said mesas and said third layer interstices so that the at least one coated fiducial has a reflectivity R5 different than the reflectivity R4 of its surroundings and so that said at least one coated fiducial is optically detectable by optical means through said additional silicon layer and said second layer.

8. A photovoltaic module comprising at least one photovoltaic device according to claim 6.

9. Method for manufacturing of a silicon structured device according to claim 1, comprising the steps (a-c) of:
a. providing a silicon-based substrate having an n-type or a p-type doping and comprising an intrinsic amorphous a-Si:H layer situated on a first face of said silicon-based substrate;
b. realizing, on said intrinsic layer, a first deposition of an n-type or p-type amorphous silicon layer, so as to create a patterned amorphous silicon layer comprising a plurality of distinct and separated amorphous layer islands separated by interstices;
c. realizing on each of said amorphous layer islands a second deposition of a nano-crystalline layer having the same doping type as said amorphous layer , so as to create on top of each of said amorphous layer islands, nano-crystalline layer portions, to form an array of silicon structures, while choosing the thickness of said first amorphous layer portions so that at least one fiducial is formed that has a different optical reflectivity , defined to the side away from said substrate, than the reflectivity of the said intrinsic amorphous silicon (a-Si:H(i)) layer portions.

10. Method according to claim 9 wherein the deposition of said amorphous layer islands and the deposition of the nanocrystalline layer islands are made through the same mechanical mask.

11. Method of realizing a photovoltaic device comprising the steps of:
providing a silicon structured device fabricated according to the steps of claim 9;
performing after step c, a step d consisting in depositing, on top of the silicon structures , and said intrinsic amorphous silicon (a-Si:H(i)) layer portions, a full area semiconductor layer, having a doping type different than the doping type of said second nano-crystalline layer so that said at least one fiducial may be detected by optical means through said full area semiconductor layer.

12. Method according to claim 11, wherein after said step d, a step e is realized consisting in depositing a second layer on top of said semiconductor layer and so that said at least one fiducialmay be detected by optical means through said full area semiconductor layer and second layer.

13. Method according to claim 12, wherein the thickness of said second layer is chosen so that, by constructive interference, reflected light off said at least one fiducial is transmitted through said second layer, in at least one wavelength range defined in the UV, visible or infrared optical spectrum.

14. Method according to claim 9, wherein the realization of said at least one fiducial is made by using a mask comprising at least one conical shape aperture, said conical shape being defined in at least one plane orthogonal to said horizontal X-Y plane and so that at least one fiducial has a greater height than said electric charge collection structures.

15. A photovoltaic device comprising the silicon structured device of claim 1.

16. A photovoltaic module comprising at least one said photovoltaic device according to claim 6.

17. The silicon structured device of claim 2, wherein the absolute value of (R1-R0)/R0 is between 0.005 and 0.1 for at least one wavelength.

18. The silicon structured device of claim 2, wherein the absolute value of (R1-R0)/R0 is between 0.09 and 0.2 for at least one wavelength.

19. The silicon structured device according to claim 2, comprising at least two fiducials.

20. The silicon structured device according to claim 2, wherein at least one of said fiducials has a different shape and/or or different dimension, in at least one cross section plane, than the shape and/or the dimension of said silicon structures.
